(19) United States
(12) Patent Application Publication
(10) Pub. No.: US 2003/0075779 A1
(43) Pub. Date: Apr. 24, 2003

(54) Semiconductor device and method for manufacturing the same

(76) Inventor: Takayuki Kito, Kyoto (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/274,965

(22) Filed: Oct. 22, 2002

(30) Foreign Application Priority Data
Oct. 24, 2001 (JP) 2001-326590

(51) Int. Cl. H01L 27/082

(52) U.S. Cl. 257/565

(57) ABSTRACT

A semiconductor device in which a transistor having a first conduction type collector layer, a second conduction type base layer and a first conduction type emitter layer is formed on a semiconductor substrate. The device includes an insulating layer formed on the semiconductor substrate and having a contact hole for connecting an electrode to the base layer, a diffusion source layer formed in the contact hole and containing an impurity for controllably imparting the second conduction type, and a high concentration region formed in the vicinity of a boundary surface between the base layer and the diffusion source layer in the base layer, the high concentration region being formed smaller in thickness than the base layer, containing the same kind of impurity as the impurity contained in the diffusion source layer, and having an impurity concentration higher than the average impurity concentration of the base layer.

### BACKGROUND OF THE INVENTION

1. Field of the Invention

The present invention relates to a semiconductor device having a transistor and a method for manufacturing the same, and particularly to a semiconductor device having a high frequency transistor and a method for manufacturing the same.

2. Description of Related Art

A high frequency transistor is manufactured with a micropattern for improving its characteristics. On a semiconductor substrate provided with a transistor, formed is a silicon oxide layer having contact holes. Through the contact holes, a base draw-out electrode is connected to a base layer and an emitter draw-out electrode is connected to an emitter.

In order to reduce contact resistance, a high concentration region having a high impurity concentration is formed in a base layer portion which is in contact with the base draw-out electrode. For example, in manufacturing a semiconductor device having an npn-type transistor, first, boron (B) ions are directly injected through the contact hole into the base layer. Thereafter, by heating the semiconductor substrate in this state, the injected boron ions are diffused to form a p⁺ layer having a high boron concentration in the base layer within a region of the contact hole, and the base draw-out electrode is formed so as to contact the p⁺ layer.

However, in the above-mentiond manufacturing method, injected boron cannot effectively contribute to reduction of contact resistance between the base layer and the base draw-out electrode, because injected boron is diffused to deep portions of the base layer by the following thermal diffusion. Therefore, high contact resistance (parasite resistance) occurs in a boundary surface between the base layer and the base draw-out electrode of the obtained semiconductor device. When a device pattern is fine, the width of a contact hole is below 1 μm. In accordance therewith, the contact area between the base layer and the base draw-out electrode becomes smaller, so that contact resistance remarkably rises.

### SUMMARY OF THE INVENTION

An object of the present invention is to provide a semiconductor device having a transistor in which contact resistance of a base layer is low.

Another object of the present invention is to provide a method for manufacturing a semiconductor device having a transistor in which contact resistance of a base layer is low.

A semiconductor device according to the present invention is one in which a transistor having a first conduction type collector layer, a second conduction type base layer and a first conduction type emitter layer is formed on a semiconductor substrate. This semiconductor device includes an insulating layer formed on the semiconductor substrate and having a contact hole for connecting the base layer to an electrode, a diffusion source layer formed in the contact hole and containing an impurity for controllably imparting the second conduction type and a high concentration region formed in the vicinity of a boundary surface between the base layer and the diffusion source layer in the base layer, the high concentration region being formed much smaller in thickness than the base layer, containing the same kind of impurity as the impurity contained in the diffusion source layer, and having an impurity concentration higher than the average impurity concentration of the base layer.

When such a semiconductor device having a diffusion source layer is heat-treated in the manufacturing process, the impurity for controllably imparting the second conduction type is diffused from the diffusion source layer into the base layer, to form a high concentration region in the vicinity of a boundary surface between the base layer and the diffusion source layer in the base layer.

When the impurity is diffused from the diffusion source layer as mentioned above, the impurity is not diffused to a deep portion of the base layer, unlike the case that an impurity directly injected into a base layer is diffused in the conventional art. Therefore, the impurity diffused from the diffusion source layer is distributed, much thinner in comparison with the thickness of the base layer, in the vicinity of a boundary surface between the base layer and the diffusion source layer in the base layer of the obtained semiconductor device. Thereby formed is the high concentration region capable of effectively contributing to reduction of contact resistance of the base layer. When the width of the contact hole is as small as below 1 μm, the contact area of a connecting portion of the base layer becomes small, so that a remarkable effect of reducing contact resistance can be obtained by the structure of the present invention.

When the second conduction type is p-type, the impurity for controllably imparting the second conduction type can be boron (B), for example.

An epitaxial growth layer may be formed on the semiconductor substrate. In this case, the transistor can be formed in the epitaxial growth layer.

The insulating layer may be further provided with an emitter contact hole, and with an emitter draw-out electrode formed through the emitter contact hole.

When the base layer includes an intrinsic base layer and an outer base layer, the outer base layer is preferably formed below the above-mentioned contact hole.

Further, the outer base layer is preferably formed thicker than the intrinsic base layer. With such a structure, contact resistance can be reduced.

The diffusion source layer is preferably formed mainly of polysilicon.

A base draw-out electrode formed of metal or the like can be provided on the diffusion source layer. In this case, the polysilicon made conductive by adding an impurity has, in addition to a function as a diffusion source layer, another function of electrically connecting the base layer and the base draw-out electrode to each other.

A method for manufacturing a semiconductor device according to the present invention is a method for manufacturing a semiconductor device by fabricating, on a semiconductor substrate, a transistor comprising a first conduction type collector layer, a second conduction type base layer and a first conduction type emitter layer. This method includes a step of forming, on the semiconductor substrate, an insulating layer having a contact hole in a part of a region corresponding to the base layer, a step of forming, in the contact hole, a diffusion source layer containing an impurity for controllably imparting the second conduction type and a step of diffusing the impurity for controllably imparting the second conduction type from the diffusion source layer to the base layer.

The step of diffusing the impurity for controllably imparting the second conduction type from the diffusion source layer to the base layer can be a heating step typically comprising lamp annealing, for example. Since temperature rise rate and temperature drop rate can be increased in lamp annealing, the impurity diffusion can be carried out in a short time.

In the case that the base layer includes an intrinsic base layer and an outer base layer, the above-mentioned method preferably further includes a step of forming an outer base layer below the region corresponding to the contact hole.

The outer base layer and the intrinsic base layer can be obtained, for example, by injecting a suitable impurity ions in a predetermined region of the semiconductor substrate, and then thermally diffusing the impurity ions. The outer base layer and the intrinsic base layer may be formed separately. By controlling forming conditions of the outer base layer and the intrinsic base layer, the outer base layer can be formed thicker (to a deeper portion) than the intrinsic base layer.

The step of forming the diffusion source layer preferably includes a step of forming a polysilicon layer and a step of introducing, into the polysilicon layer, an impurity for controllably imparting the second conduction type to the polysilicon layer.

Since polysilicon made conductive by adding an impurity is a conventional material as a wiring material for a semiconductor device, a semiconductor device according to the present invention can be easily manufactured using existing equipments.

The step of forming the polysilicon layer can be carried out, for example, by CVD (Chemical Vapor Deposition) method. And the step of introducing, into the polysilicon layer, an impurity for controllably imparting the second conduction type to the polysilicon layer can be carried out by ion injection, for example.

The emitter layer may be obtained by forming a polysilicon layer added with an impurity for controllably imparting the first conduction type in an emitter contact hole provided in the insulating layer, and diffusing the impurity from the polysilicon layer into the semiconductor substrate by heat-treatment. In this case, the polysilicon layer to be formed in the base contact hole and the polysilicon layer to be formed in the emitter contact hole may be formed integrally. Further, the high concentration region and the emitter layer can be formed by injecting an impurity for imparting the first conduction type into the polysilicon layer in the base contact hole and injecting an impurity for imparting the second conduction type into the polysilicon layer in the emitter contact hole, and thereafter commonly heat-treating these silicon layers.

The foregoing and other objects, features, aspects and advantages of the present invention will become more apparent from the following detailed description of embodiments of the present invention given with reference to the accompanying drawings.

### BRIEF DESCRIPTION OF THE DRAWINGS

FIG. 1 is a schematically sectional view of a semiconductor device according to an embodiment of the present invention.

FIGS. 2(a)-2(k) are schematically sectional views showing a method for manufacturing the semiconductor device shown in FIG. 1 in order of step.

### DESCRIPTION OF THE PREFERRED EMBODIMENTS

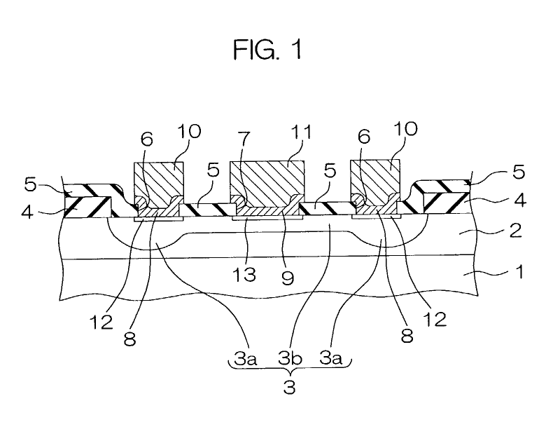

FIG. 1 is a schematically sectional view of a semiconductor device according to the present invention.

On a semiconductor substrate 1 formed of n-type silicon (Si), an epitaxial layer 2 formed of silicon is provided. The thickness of the epitaxial layer 2 can be, for example, 4 μm. The epitaxial layer 2 has been made to n-type by adding an impurity, and conductivity of the layer 2 can be, for example, 0.75 Ωcm. In the central portion of the epitaxial layer 2, a base layer 3 is formed through a predetermined depth from the surface of the epitaxial layer 2. The base layer 3 is inverted to p-type by adding an impurity (for example, boron (B)) for controllably imparting p-type conduction (hereinafter referred to as p-type impurity). The peripheral portion of the base layer 3 is formed thicker (to a deeper portion) than the remaining portion, to form outer base layer 3a. In concrete, for example, the thickness of the thickest portion of the outer base layer 3a is about 1.2 μm and the thickness of the portion other than the outer base layer 3a (an intrinsic base layer 3b) is about 0.5 μm.

A first silicon oxide layer 4 is formed on the epitaxial layer 2 having the base layer 3. The first silicon oxide layer 4 is provided with an opening in the region substantially corresponding to the base layer 3. On the first silicon oxide layer 4 and the base layer 3, a second silicon oxide layer 5 is provided. The second silicon oxide layer 5 is in contact with the upper surface of the epitaxial layer 2 (base layer 3) in the opening of the first silicon oxide layer 4. In this region, the second silicon oxide layer 5 is provided with openings, namely, an emitter contact hole 7 and base contact hole 6. In this sectional view, the emitter contact hole 7 situated in the central portion and the base contact hole 6 situated on both sides thereof. Although the base contact hole 6 is illustrated on both sides of the emitter contact hole 7, the base contact hole 6 is a curved continuous hole in plan view.

A p-type polysilicon layer 8 is provided so as to fill the base contact hole 6. The p-type polysilicon layer is formed by adding, to polysilicon, an impurity (such as boron) for controllably imparting p-type conduction. An n-type polysilicon layer 9 is provided so as to fill the emitter contact hole 7. The n-type polysilicon 9 is formed by adding, to polysilicon, an impurity (such as arsenic (As)) for controllably imparting n-type conduction (hereinafter referred to as n-type impurity).

On the p-type polysilicon layer 8, a base draw-out electrode 10 is provided. On the n-type polysilicon layer 9, an emitter draw-out electrode 11 is provided. The base draw-out electrode 10 and the emitter draw-out electrode 11 are formed of, for example, aluminum (Al), an alloy of aluminum and silicon and an alloy of aluminum and copper (Cu).

In the vicinity of a boundary surface between the base layer 3 and the p-type polysilicon layer 8 in the outer base layer 3a, provided is p⁺ layer 12 having a p-type impurity concentration higher than the average p-type impurity concentration of the base layer 3. The thickness (for example, 0.1˜0.25 μm) of the p⁺ layer 12 is much thinner than the thickness (for example, 0.5˜1.2 μm) of the base layer 3. The p-type impurity added to the p-type polysilicon layer 8 and the p-type impurity added to the p⁺ layer 12 are of the same kind with each other (for example, they may be equally boron). The p-type polysilicon layer 8, having been made conductive by the p-type impurity, electrically connects the p⁺ layer 12 with the base draw-out electrode 10.

In the vicinity of a boundary surface between the epitaxial layer 2 and the n-type polysilicon layer 9 in the epitaxial layer 2, an n-type emitter layer 13 is provided. The thickness (for example, 0.1˜0.25 μm) of the n-type emitter layer 13 is much thinner than the thickness of the base layer 3. The n-type impurity added to the n-type polysilicon layer 9 and the n-type impurity added to the emitter layer 13 are of the same kind with each other (for example, they may be equally arsenic). The n-type polysilicon layer 9, having been made conductive by the n-type impurity, electrically connects the emitter layer 13 with the emitter draw-out electrode 11.

In the above-mentioned structure, owing to the p⁺ layer 12 (impurity distributed at a high concentration in the vicinity of the surfaces of the base layer 3), resistance between the base layer 3 (outer base layer 3a) and the base draw-out electrode 10 (p-type polysilicon layer 8) can be reduced. When the pattern of the semiconductor device is fine and the width of contact hole 6 is small (for example, not more than 1 μm), the contact area between the base layer 3 and base draw-out electrode 10 (p-type polysilicon layer 8) is reduced, so that an excellent effect of resistance reduction can be obtained. As a result, an excellent high frequency transistor having a low base resistance can be realized.

Since the outer base layer 3a is formed thicker than the intrinsic base layer 3b, the resistance value of the base layer 3 is reduced.

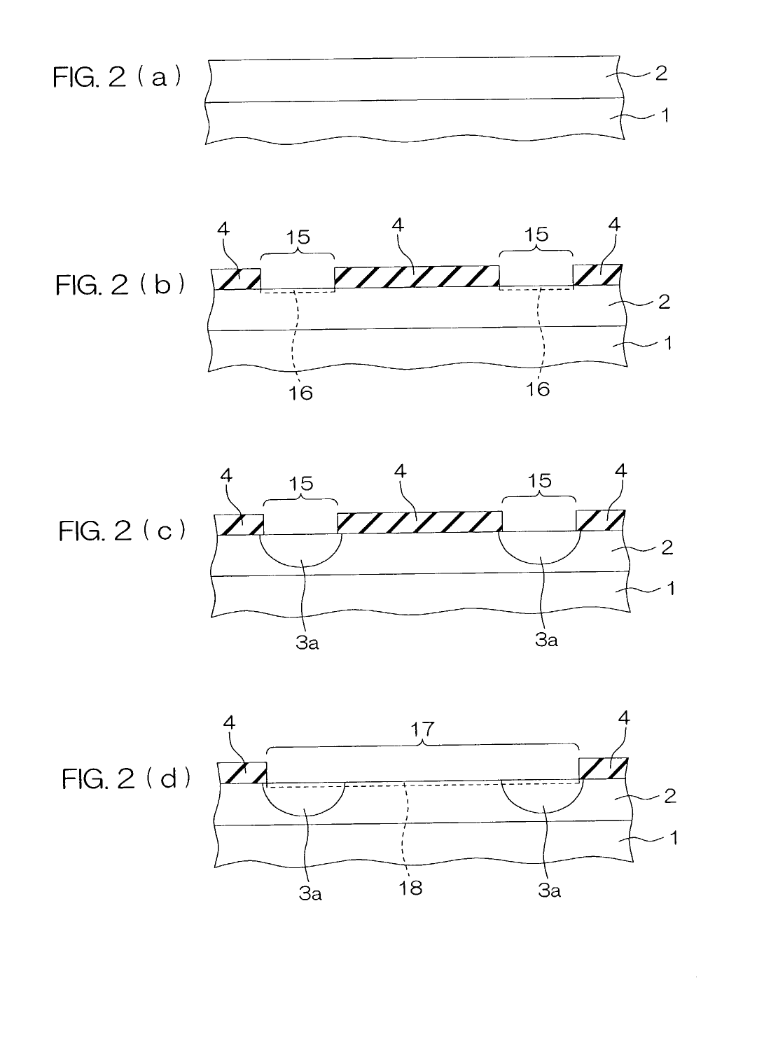

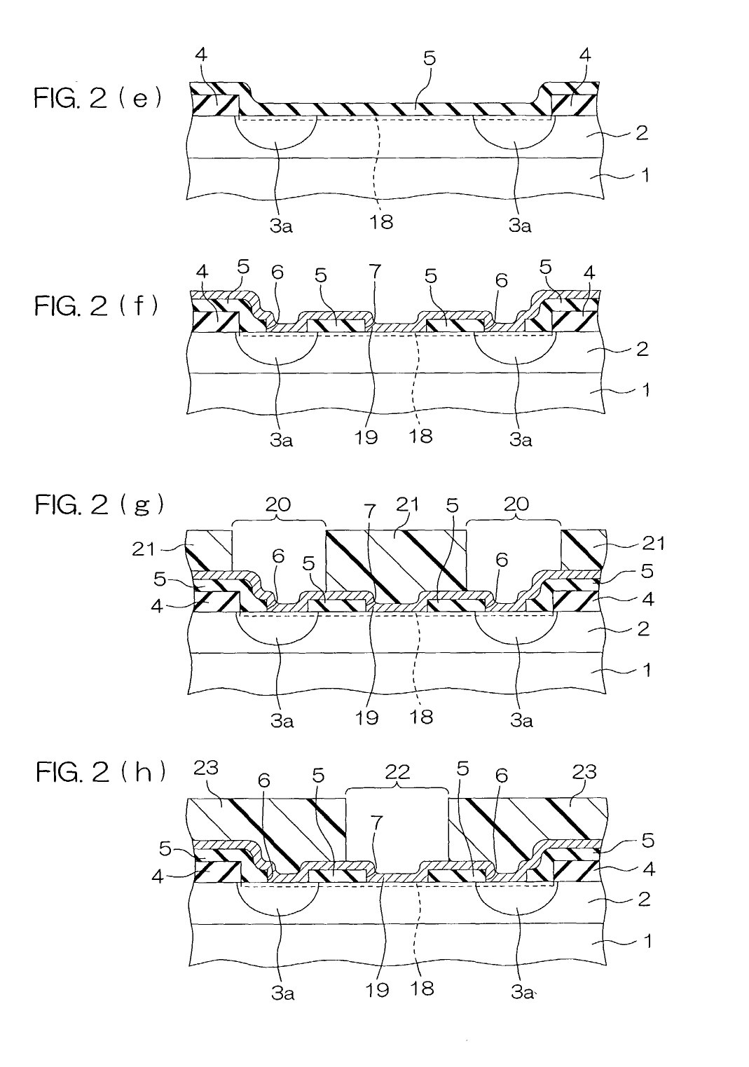

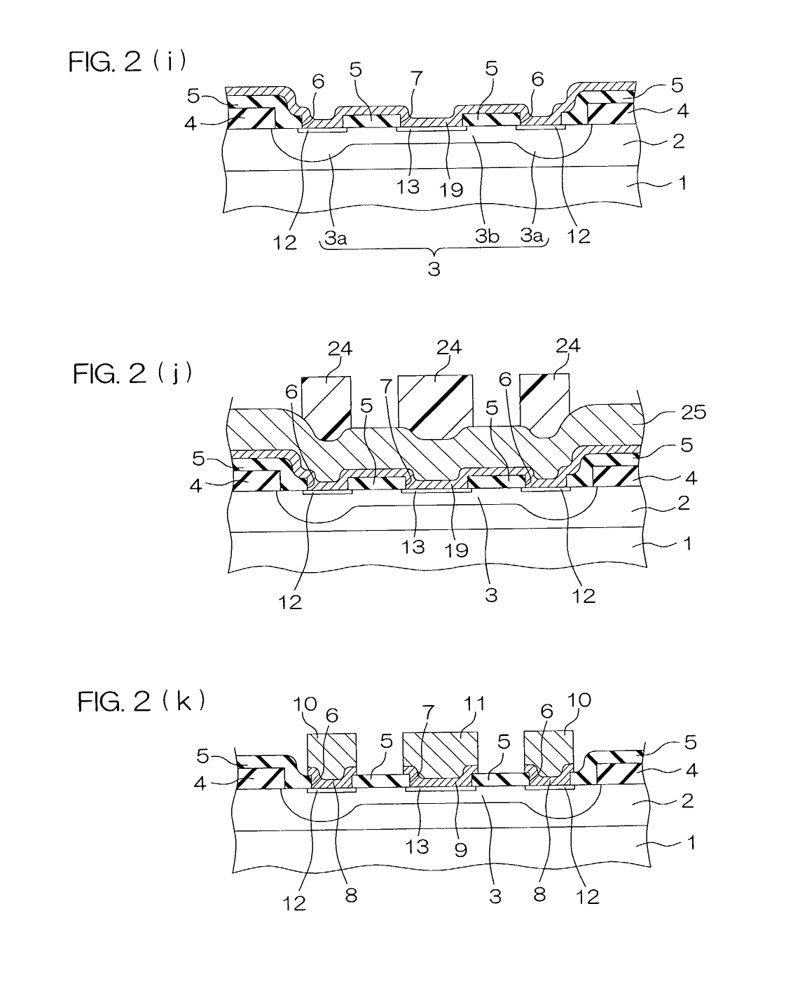

FIGS. 2(a)-2(k) are schematically sectional views showing a method for manufacturing the semiconductor device shown in FIG. 1 in order of step.

On a semiconductor substrate 1 formed of n-type silicon (Si), an epitaxial layer 2 formed of silicon is provided (FIG. 2(a)). Then, by heat-oxidizing the surface of the epitaxial layer 2, a first silicon oxide layer 4 is formed. A resist pattern is formed on the first silicon oxide layer 4 and etching is performed, so that the first silicon oxide layer 4 is provided with an opening 15 for forming an outer base layer. In this sectional view, opening 15 is situated in two parts, through it is one continuous opening in plan view. Thereafter, the resist is removed and ion injection through the opening 15 is performed so that boron is injected into the exposed surface layer 16 of the epitaxial layer 2. This state is shown in FIG. 2(b). The amount of boron injected into surface layer portion 16 can be, for example, 5×10¹⁴-5×10¹⁵ cm⁻².

Then, boron is diffused by heat-treatment to the deep portion of the epitaxial layer 2 to form outer base layer 3a (FIG. 2c). The heat-treatment comprises, for example, keeping the temperature at 1000° C. for several ten minutes. Thereafter, a resist pattern is formed and the first silicon oxide layer 4 between the two parts of opening 15 for forming the outer base layer 3a is removed away by etching, and then the resist is removed away. Thereby, the first silicon oxide layer 4 is provided with a large opening 17 for forming an intrinsic base layer including the region in which the opening 15 for forming the outerbase layer 3a has been formed. By ion injection through the opening 17 for forming the intrinsic base layer 3b, boron is injected in an exposed surface layer portion 18 of the epitaxial layer 2. This state is shown in FIG. 2(d). The concentration of boron of the surface layer portion 18 can be, for example, 1×10¹⁷-1×10¹⁸ cm⁻³.

Next, a second silicon oxide layer 5 is formed on the surface layer portion 18 of the epitaxial layer 2 and the first silicon oxide layer 4 (FIG. 2(e)). This step can be carried out by CVD method. A resist pattern is formed on the second silicon oxide layer 5 and the exposed second silicon oxide layer 5 is etched, so that required openings are provided in the second silicon oxide layer 5 on the surface layer portion 18. That is, an emitter contact hole 7 and a base contact hole 6 are obtained. In this sectional view, the emitter contact hole 7 situated in the central portion and the base contact hole 6 situated on both sides thereof. Although the base contact hole 6 is illustrated on both sides of the emitter contact hole 7, the base contact hole 6 is a curved continuous hole in plan view. After removing the resist away, a polysilicon layer 19 is formed on the second silicon oxide layer 5 and the exposed epitaxial layer 2. This step can be carried out, for example, by CVD method. This state is shown in FIG. 2(f). The thickness of the polysilicon layer 19 can be, for example, 2000-3000 Å.

Then, a resist 21 having ion injection opening 20 is formed. The ion injection opening 20 is provided in a region including the base contact hole 6 as viewed in plan view. Boron ions are injected through the ion injection opening 20 into the exposed polysilicon layer 19. Thereby, boron ions are injected into the polysilicon layer 19 only in a specified region including the base contact hole 6 as viewed in plan view, thus to make conductive the polysilicon layer 19 in the region injected with boron ions. This state is shown in FIG. 2(g). The amount of boron injected into the polysilicon layer 19 in this region can be, for example, 5×10¹⁴-5×10¹⁵ cm⁻². Thereafter, the resist 21 is removed away.

Then, a resist 23 having ion injection opening 22 is formed. The ion injection opening 22 is provided in a region including the emitter contact hole 7 as viewed in plan view. Arsenic ions are injected through the ion injection opening 22 into the exposed polysilicon layer 19. Thereby, arsenic ions are injected into the polysilicon layer 19 only in a specified region including the emitter contact hole 7 as viewed in plan view, thus to make conductive the polysilicon layer 19 in the region injected with arsenic ions. This state is shown in FIG. 2(h). The amount of arsenic injected into the polysilicon layer 19 in this region can be, for example, 5×10¹⁴-5×10¹⁵ cm⁻². Thereafter, the resist 23 is removed away.

Thereafter, the semiconductor substrate 1 in this state is heated. In this heating step, a variety of conventional heating methods can be applied, and lamp annealing can be adopted, for example. By adopting lamp annealing, both of the temperature rising rate and the temperature dropping rate can be increased, so that the impurity diffusion can be carried out in a short time.

When the semiconductor substrate 1 is heated, boron injected into the surface layer portion 18 is diffused to the deep portion of the epitaxial layer 2, whereby a intrinsic base layer 3b is formed. The boron diffusion is controlled by conditions of the heat-treatment at this time, and the thickness of the intrinsic base layer 3b is made thinner than that of the thickest portion of the outer base layer 3a. The outer base layer 3a and the intrinsic base layer 3b form a continuous base layer 3.

At the same time, from the polysilicon layer 19 acting as a diffusion source layer, injected boron and arsenic are diffused into the epitaxial layer 2 directly under the base contact hole 6 and the emitter contact hole 7 to form p⁺ layer 12 and an emitter layer 13, respectively. The diffusion of boron and arsenic is controlled by the conditions (time, temperature and the like) of the heat-treatment (annealing) and each of the thicknesses of the p⁺ layer 12 and an emitter layer 13 is made much smaller than the thickness of the base layer 3. In other words, the conditions of the heat-treatment are set in such a manner that the thickness of the intrinsic base layer 3b becomes thinner than that of the thickest portion of the outer base layer 3b and each of the thicknesses of the p⁺ layer 12 and an emitter layer 13 becomes much thinner than the thickness of the base layer 3. This state is shown in FIG. 2(i).

Then, a metal layer 25 is formed on the polysilicon layer 19. The metal layer 25 can be formed of aluminum, an alloy of aluminum and silicon, an alloy of aluminum and copper or the like. This step can be carried out by sputtering method, for example. And a pattern of a resist 24 is formed on the metal layer 25. The resist 24 is disposed so as to cover the upper portion of the base contact hole 6 and the emitter contact hole 7 (FIG. 2(j)).

The exposed metal layer 25 is removed by etching with the use of the resist 24 acting as a mask. Further, the exposed polysilicon layer 19 after removing the metal layer 25 is similarly removed by etching with the same resist 24 acting as a mask. After these steps, the polysilicon layer 19 and the metal layer 25 remaining inside and in the upper portion of the base contact hole 6 form n-type polysilicon layer 8 and base draw-out electrode 10, respectively. Further, the polysilicon layer 19 and the metal layer 25 remaining inside and in the upper portion of the emitter contact hole 7 form an n-type polysilicon layer 9 and an emitter takeout electrode 11, respectively.

Finally, the resist 24 is removed away, and the semiconductor substrate 1 is heat-treated to sinter the base draw-out electrode 10 and the emitter draw-out electrode 11, so that the semiconductor device shown in FIG. 1 can be obtained (FIG. 2(k)).

Since the base layer 3 is formed thicker (to a deeper portion) in the portions below the base draw-out electrode 10 or in the portion of the outer base layer 3a than the other portion, the resistance value can be reduced. However, it is not always necessary that the base layer 3 has variation in thickness thereof. In this case, the steps of forming the outer base layer 3a (FIGS. 2(b), (c)) need not be carried out.

The above-mentioned embodiments are examples in which the transistor is of npn-type, but the transistor may be of pnp-type.

Although the present invention has been described and illustrated in detail, it is clearly understood that the same is by way of illustration and example only and is not to be taken by way of limitation, the spirit and scope of the present invention being limited only by the terms of the appended claims.

This application corresponds to the Japanese Patent Application No. 2001-326590 filed in the Japan Patent Office on Oct. 24, 2001, and the whole disclosure of the Japanese application is incorporated herein by reference.

What is claimed is:

1. A semiconductor device in which a transistor having a collector layer of a first conduction type, a base layer of a second conduction type and an emitter layer of the first conductive type are formed on a semiconductor substrate, comprising:
an insulating layer formed on the semiconductor substrate and having a base contact hole for connecting an electrode to the base layer;
a diffusion source layer formed in the contact hole and containing an impurity for controllably imparting the second conduction type; and
a high concentration region formed in a vicinity of a boundary surface between the base layer and the diffusion source layer in the base layer, the high concentration region being formed smaller in thickness than the base layer, containing a same kind of impurity as the impurity contained in the diffusion source layer, and having an impurity concentration higher than an average impurity concentration of the base layer.

2. A semiconductor device according to claim 1, wherein the base layer includes an intrinsic base layer and an outer base layer, and the outer base layer is formed below the base contact hole.

3. A semiconductor device according to claim 1, wherein the diffusion source layer is mainly formed of polysilicon.

4. A method for manufacturing a semiconductor device by forming, on a semiconductor substrate, a transistor having a collector layer of a first conduction type, a base layer of a second conduction type and an emitter layer of the first conduction type, the method comprising steps of:
forming, on the semiconductor substrate, an insulating layer having a base contact hole in a part of a region corresponding to the base layer;
forming, in the base contact hole, a diffusion source layer containing an impurity for controllably imparting the second conduction type; and
diffusing the impurity for controllably imparting the second conduction type from the diffusion source layer to the base layer.

5. A method according to claim 4, wherein the step of diffusing the impurity for controllably imparting the second conduction type from the diffusion source layer to the base layer includes a heating process by lamp annealing.

6. A method according to claim 4, wherein the base layer includes an intrinsic base layer and an outer base layer, and the method further comprises a step of forming outer base layer below a region corresponding to the base contact hole.

7. A method according to claim 4, wherein the step of forming the diffusion source layer includes steps of;
forming a polysilicon layer, and
introducing an impurity for controllably imparting the second conduction type into the polysilicon layer.

8. A method according to claim 7, wherein
the step of forming the insulation layer includes a step of forming the insulating layer having an emitter contact hole in addition to the base contact hole, and
the step of forming polysilicon layer includes a step of forming the polysilicon layer entering the base contact hole and the emitter contact hole,
the method further comprising steps of;
introducing an impurity for controllably imparting the first conduction type into a region of the emitter contact hole, and
diffusing the impurity for controllably imparting the first conduction type from the polysilicon layer in the region of the emitter contact hole to the semiconductor substrate so as to form the emitter layer.

9. A method according to claim 8, wherein the step of diffusing the impurity for controllably imparting the second conduction type from the diffusion source layer to the base layer and the step of forming the emitter layer include a common step of heating of diffusing the impurity.
